(19) United States
(12) Patent Application Publication
(10) Pub. No.: US 2007/0160448 A1
(43) Pub. Date: Jul. 12, 2007

(54) RECEIPT AND DELIVERY CONTROL SYSTEM FOR FRONT OPENING UNIFIED AND RETICLE STORAGE PODS

(75) Inventors: Benjamin R. Wheeler, Mount Kisco, NY (US); Jeffrey P. Gifford, Fishkill, NY (US); David J. Pinckney, Newtown, CT (US); Uldis A. Ziemins, Poughkeepsie, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 11/306,679

(22) Filed: Jan. 6, 2006

(51) Int. Cl. H01L 21/677

(52) U.S. Cl. 414/217

(57) ABSTRACT

The invention is directed to a method and system for pod transportation within a semiconductor fabrication facility. The invention comprises a material control system that determines a pod that a station will require next and then sends an instruction to a vehicle to receive the pod that the station currently has and deliver the pod that the station will require next. The invention reduces cycle time by minimizing transportation moves of vehicles within the semiconductor fabrication facility.

### BACKGROUND OF THE INVENTION

1. Field of the Invention

The invention relates generally to semiconductor manufacturing, and more particularly to an improved receipt and delivery control system for front opening unified pods (FOUP) and reticle storage pods (RSP) within a semiconductor fabrication facility.

2. Description of the Related Art

Reduction of semiconductor processing cycle time is of utmost importance within a semiconductor fabrication facility. Transportation moves within a semiconductor fabrication facility increase semiconductor processing cycle time. Therefore, it has become increasingly important to reduce transportation moves within a semiconductor fabrication facility.

The prior art method for FOUP/RSP receipt and delivery within a semiconductor fabrication facility is depicted in FIG. 1. The prior art method comprises a serial communication system, which will be discussed with reference to steps 102-114 in FIG. 1. According to the prior art method, once a station has finished with a pod in step 102, the station sends a completion notice to a material control system in step 104. Generally, the station comprises a semiconductor process tool and the completion notice indicates that the semiconductor process tool has completed a process on the contents of a FOUP. However, a station could also comprise a storage container and a pod could also comprise a RSP. In accordance with the prior art method, the MSP sends a receipt instruction to a vehicle in the semiconductor fabrication facility in step 106 and a vehicle receives the FOUP or RSP from the station in step 108. After the vehicle receives the pod from the station, the MSP determines which pod the station requires next in step 110. The MSP sends a receipt instruction to another vehicle in the semiconductor fabrication facility in step 112. The other vehicle delivers the next pod to the station in step 114.

The prior art method is problematic because the MSP does not efficiently determine and subsequently send receipt and delivery instructions to the vehicles in the semiconductor fabrication facility. The MSP does not determine which pod a station requires next until after the vehicle receives the pod from the station. A more efficient receipt and delivery instruction is necessary to reduce semiconductor processing cycle time.

What is needed in the art is an improved FOUP/RSP receipt and delivery control system for semiconductor fabrication facilities that reduces semiconductor processing cycle time.

### BRIEF SUMMARY OF THE INVENTION

The invention comprises a method for pod transportation within a semiconductor fabrication facility comprising the steps of receiving, determining, and sending. The receiving step comprises receiving a completion notice of a process performed on the contents of a pod from one of the stations in the semiconductor fabrication facility. The determining step comprises determining which pod the station requires next. The sending step comprises sending an instruction to a vehicle in the semiconductor fabrication facility to receive the pod that the station finished processing from the station and deliver the pod that the station requires next to the station.

The invention comprises a system for pod transportation within a semiconductor fabrication facility comprising vehicles, stations, and a material control system (MCS). Each vehicle comprises at least two compartments for receiving or delivering a pod through the semiconductor fabrication facility and a communication system that receives an instruction regarding receipt and delivery of pods. Each process tool receives a pod from the vehicles, performs a process on contents of the received pod, and sends a notice upon completion of the process. The MCS has a communication system that receives the completion notice from one of the stations, determines the pod that the station requires next, and sends an instruction to one of the vehicles to receive the first pod from the station and deliver the required second pod to the station.

The invention is directed to an improved pod transportation system and method within a semiconductor fabrication facility. The invention reduces vehicle transportation time within a semiconductor fabrication facility. Therefore, the invention reduces semiconductor processing cycle time.

For at least the foregoing reasons, the invention improves upon pod transportation within a semiconductor fabrication facility.

### BRIEF DESCRIPTION OF THE DRAWINGS

The features and the element characteristics of the invention are set forth with particularity in the appended claims. The figures are for illustrative purposes only and are not drawn to scale. Furthermore, like numbers represent like features in the drawings. The invention itself, however, both as to organization and method of operation, may best be understood by reference to the detailed description which follows, taken in conjunction with the accompanying figures, in which:

FIG. 1 depicts the prior art method for FOUP/RSP receipt and delivery within a semiconductor fabrication facility.

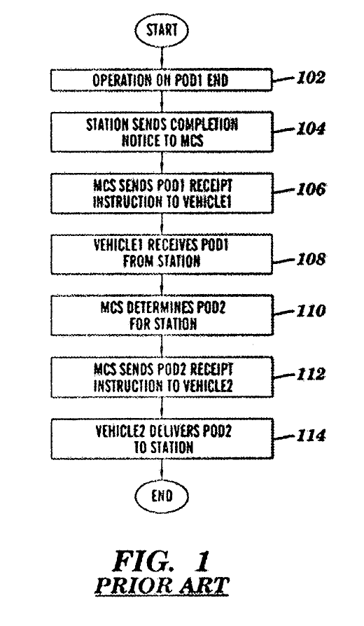

FIG. 2 depicts the method for FOUP/RSP receipt and delivery within a semiconductor fabrication facility in accordance with the invention.

FIG. 3 depict the system for FOUP/RSP receipt and delivery within a semiconductor fabrication facility in accordance with the invention.

### DETAILED DESCRIPTION OF THE INVENTION

The invention will now be described with reference to the accompanying figures. In the figures, various aspects of the structures have been depicted and schematically represented in a simplified manner to more clearly describe and illustrate the invention.

By way of overview and introduction, the invention is directed to an improved method and system for FOUP and/or RSP receipt and delivery within a semiconductor fabrication facility. Upon receipt of a completion notice from a station within the semiconductor fabrication facility, the MCS determines which pod a station requires next and sends a vehicle an instruction to receive the pod that the station finished processing and deliver to the pod that the station requires next. Upon arriving at the station with the next required pod, the vehicle executes combined pick-up of completed previous pod and delivery of next pod.

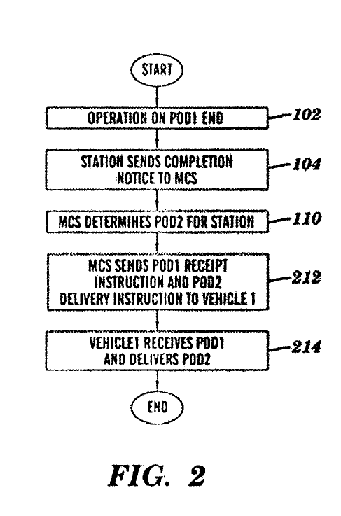

FIG. 2 depicts the method for FOUP/RSP receipt and delivery within a semiconductor fabrication facility in accordance with the invention. Once a station has finished with a pod in step 102, the station sends a completion notice to the MCS in step 104. In accordance with the invention the MCS determines which pod the station requires next in step 110, prior to sending an instruction to a vehicle to receive the pod that the station finished processing. After the MCS has determined which pod the station requires next in step 110, the MCS sends a single vehicle both an instruction to receive the pod that the station finished processing and to deliver the pod that the station requires next in step 212. Unlike the prior art, which required two separate vehicles, one vehicle for receipt of the pod that the station finished processing and another for delivery of the pod that the station required next, the invention requires a single vehicle. The MCS then sends both the receipt and delivery instruction to a single vehicle in step 212. The invention, therefore frees the second vehicle for other transportation jobs, while at the same time minimizing the number of transportation moves of the single vehicle. In step 214, the single vehicle both receives the first pod from the station and delivers the second pod in a combined, single transaction.

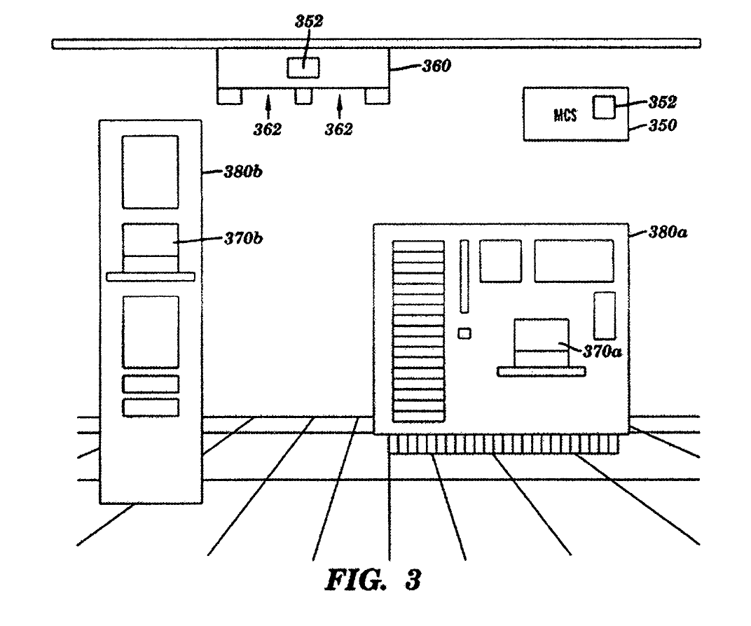

FIG. 3 depicts the system for FOUP/RSP receipt and delivery within a semiconductor fabrication facility in accordance with the invention. As discussed herein above a single vehicle 360 receives the instruction from the MCS 350 to both receive the pod 370a that the station 380a finished processing and deliver the pod 370b that the station 380a requires next. As shown in FIG. 3, the pod 370b that the station 380a requires next is in a storage container 380b. As mentioned herein above, a pod 370 comprises either a FOUP or a RSP and a station 380 comprises either a semiconductor process tool or a storage container. As also mentioned herein above, the MCS 350 sends this instruction through a communication system 352 to a single vehicle 360. As depicted in FIG. 3, the single vehicle comprises at least two compartments 362 for receipt and delivery of pods.

The invention efficiently handles the receipt and delivery of pods within a semiconductor fabrication facility through the use of a MCS that determines which pod a station requires next and then sends an instruction to a single vehicle to both receive the pod that the station finished processing and deliver the pod that the station requires next. In so doing, the invention reduces cycle time within the semiconductor fabrication facility.

While the invention has been particularly described in conjunction with a specific preferred embodiment and other alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the invention.

What is claimed is:

1. A system for pod transportation within a semiconductor fabrication facility, comprising:
a plurality of vehicles, each vehicle comprising at least two compartments for one of receiving and delivering a pod through said semiconductor fabrication facility and a communication system that receives an instruction regarding receipt and delivery of said pods;
a plurality of stations, a station receiving a first pod from one of said plurality of vehicles, performing a process on contents of said received first pod, and sending notice upon completion of said process;
a material control system (MCS) with a communication system that receives said completion notice from one of said plurality of stations, determines a second pod said station requires next, and sends an instruction to one of said plurality of vehicles to receive said first pod from said station and deliver said required second pod to said station.

2. A system as in claim 1, said pod comprises one of a reticle storage pod (RSP) and front opening unified pod (FOUP).

3. A system as in claim 1, said station comprises one of a semiconductor process tool and storage container.

4. A system as in claim 1, said MCS further determines which station in said semiconductor fabrication facility requires said first pod next and includes in said instruction to said one of said plurality of vehicles delivery of said first pod to said required second station.

5. A method for pod transportation within a semiconductor fabrication facility, comprising:
receiving a completion notice of a process performed on contents of a first pod, said first pod one of a plurality of pods in a semiconductor fabrication facility, from a first station, said first station one of a plurality of stations;
determining which second pod in said plurality of pods said first station requires next in response to said received notice;
sending an instruction to a vehicle in said semiconductor fabrication facility to receive said first pod from said station in said semiconductor fabrication facility and deliver said determined second pod to said station.

6. A method as in claim 5, said pod comprises one of a reticle storage pod (RSP) and front opening unified pod (FOUP).

7. A method as in claim 5, said station comprises one of a semiconductor process tool and storage container.

8. A method as in claim 5, said determining step further comprising determining which station in said semiconductor fabrication facility requires said first pod next.

9. A method as in claim 8, said sending step further comprising said instruction to deliver said first pod to said required second station.
